(19) United States
(12) Patent Application Publication
(10) Pub. No.: US 2013/0221991 A1
(43) Pub. Date: Aug. 29, 2013

(54) USER INTERFACE HAVING UNIVERSAL SENSING ELECTRODE STRUCTURE

(71) Applicant: TOUCHSENSOR TECHNOLOGIES, LLC, (US)

(72) Inventor: Robert B. Campbell, Naperville, IL (US)

(73) Assignee: TOUCHSENSOR TECHNOLOGIES, LLC, Wheaton, IL (US)

(21) Appl. No.: 13/780,914

(22) Filed: Feb. 28, 2013

Related U.S. Application Data
(60) Provisional application No. 61/604,923, filed on Feb. 29, 2012.

(51) Int. Cl. G01R 27/26

(52) U.S. Cl. CPC G01R 27/2605
USPC 324/658

(57) ABSTRACT

A universal sensor array for use with a user interface panel includes a first array of conductors separated from a second array of conductors by a dielectric substrate. Conductors of the first array cross over the conductors of the second array without touching. A control circuit detects stimuli proximate the conductors and provides respective control outputs in response to substantially simultaneous detection of stimuli proximate predetermined pairs of intersecting conductors and provides a null control output in response to detection of stimuli proximate other conductors or pairs of conductors.

### CROSS REFERENCE TO RELATED APPLICATIONS

This application claims the benefit of priority under 35 U.S.C. §119(e) to U.S. Provisional Patent Application No. 61/604,923, filed Feb. 29, 2012, the disclosure of which is incorporated herein by reference in its entirety

### BACKGROUND OF THE INVENTION

User interfaces including electronic sensors, for example, field effect sensors or capacitive sensors, are known in the art. Such user interfaces commonly include a touch panel having an outer surface that is decorated to identify the sensor locations and/or the functions they control. The sensors themselves typically are embodied as one or more discrete sensing electrodes and an associated control circuit located on a separate circuit carrier, for example, a printed wiring board, that is attached to the opposite surface of the touch panel. The sensing electrodes are disposed on the circuit carrier in an arrangement that corresponds to the arrangement of the foregoing decorations on the touch panel. The sensors respond to stimuli, for example, a user's fingertip or other object, touching or coming into proximity with the corresponding portions of the panel.

The sensing electrodes typically are formed by printing conductive ink onto the circuit carrier or by patterning and etching a conductive layer disposed on the circuit carrier, as would be understood by one skilled in the art. Once the sensing electrodes are formed, their locations on the carrier are fixed. Subsequent changes to the sensing electrode arrangement would be difficult, if not impossible.

### BRIEF DESCRIPTION OF THE DRAWINGS

FIG. 1 is an exploded perspective view of a first array of generally elongated sensing electrodes disposed between a first pair of dielectric sheets;

FIG. 2 is a perspective view of a first array of generally elongated sensing electrodes disposed between a first pair of dielectric sheets;

FIG. 3 is an exploded perspective view of a first array of generally elongated sensing electrodes disposed between a first pair of dielectric sheets and a second array of sensing electrodes disposed between a second pair of dielectric sheets;

FIG. 4 is a plan view of the structure of FIG. 3;

FIG. 5 is a plan view of the structure of FIG. 3 with the dielectric sheets removed for clarity;

FIG. 6 is an exploded perspective view of a user interface including the structure of FIG. 3 and having a first configuration of touch surfaces;

FIG. 7 is a perspective view of a user interface including the structure of FIG. 3 and having a second configuration of touch surfaces;

FIG. 8 is a perspective view of a user interface including the structure of FIG. 3 and having a third configuration of touch surfaces; and

FIG. 9 is a perspective view of a user interface including the structure of FIG. 3 and having a fourth configuration of touch surfaces.

### DETAILED DESCRIPTION OF THE DRAWINGS

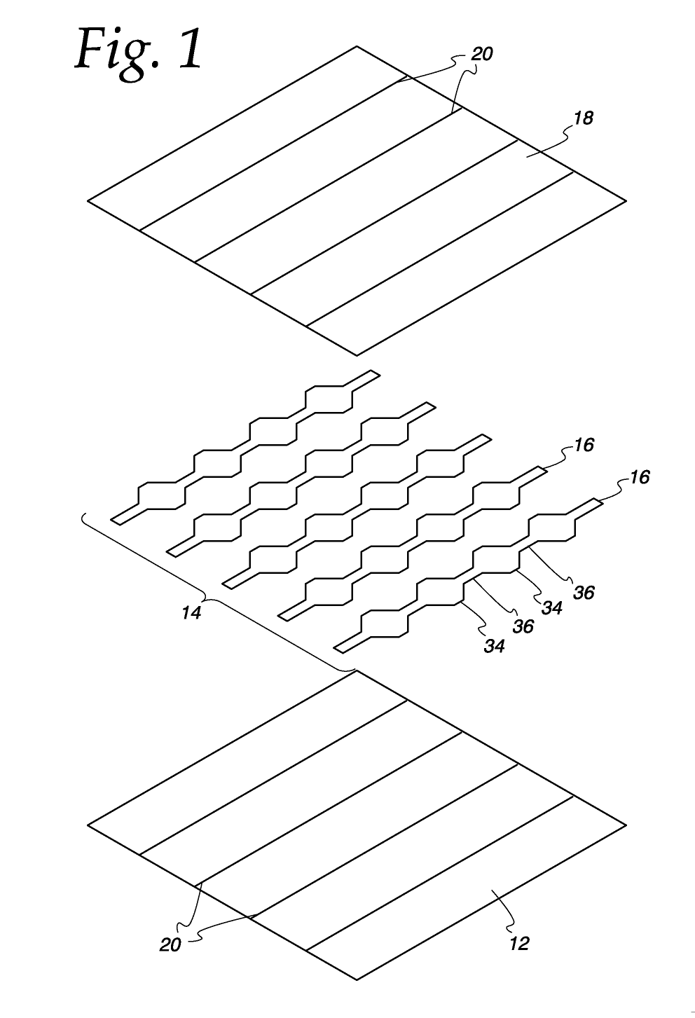

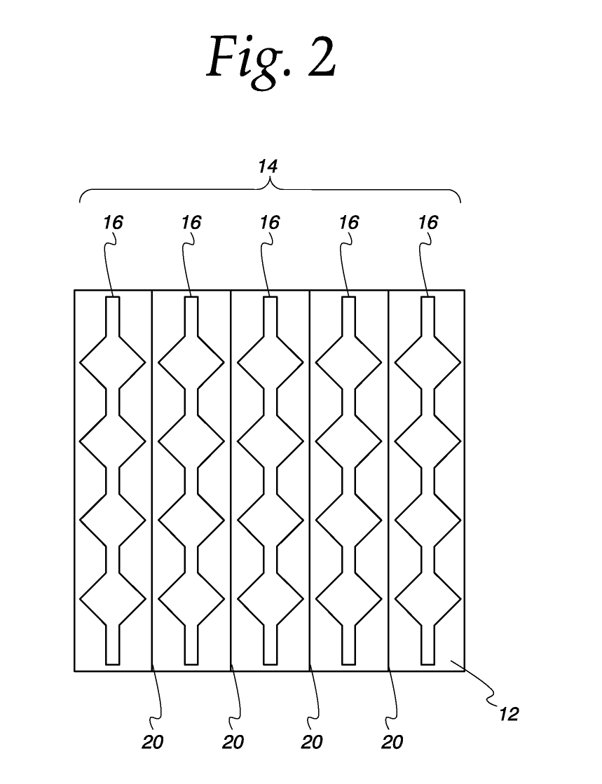

FIGS. 1 and 2 illustrate a conductor assembly 10 including an array 14 of generally elongated conductors (or electrodes) 16 disposed between a first substrate 12 and a second substrate 18. (First substrate 12 may sometimes be referred to herein as lower substrate 12, and second substrate 18 may sometimes be referred to herein as upper substrate 12. Such references are for clarity, convenience and illustration and shall not be construed as limiting the scope of the present invention.) First and second substrates 12, 18 could be made of any material suitable for use as an electrical circuit platform. For example, either or both of substrates 12, 18 could be made of polyester, FR4, plastic, glass and the like. Also, either or both of substrates 12, 18 could be flexible or rigid, and either or both could be transparent, translucent or opaque. Conductors 16 could be made of any suitable conductive material, for example, copper, silver, ITO, or one or more other materials as would be understood by one skilled in the art. Conductors 16 could be transparent, translucent or opaque.

Conductors 16 could be disposed between substrates 12 and 18 in any suitable manner, as would be recognized by one skilled in the art. For example, conductors 16 could be formed by plating, patterning and etching copper or another suitable conductive material on substrate 12 as one might fabricate a printed wiring board. Alternatively, conductors 16 could be made of conductive ink printed onto substrate 12 using a screen printing process or any other suitable process, as would be recognized by one skilled in the art. As a further alternative, conductors 16 could be preformed and placed onto substrate 12. For example, conductors 16 could be stampings made of copper or another conductive material placed onto or otherwise disposed upon substrate 12. An adhesive could be disposed between substrate 12 and such preformed conductors 16 to preclude inadvertent movement of the preformed conductors with respect to substrate 12 once placed onto substrate 12.

Substrate 18 could be disposed on conductors 16 and exposed portions of substrate 12. Substrate 18 could be joined to substrate 12 using any suitable means. In the illustrated embodiments, substrate 18 is joined to substrate 12 by means of ultrasonically-formed welds 20. Alternatively, an adhesive could be used to join substrate 18 to substrate 12 (and, optionally, to conductors 16). A combination of these techniques could be used, as well. One skilled in the art would recognize that substrate 18 could be joined to substrate 12 in other ways, as well.

Conductor assembly 10 also could be produced in bulk and/or on a substantially continuous basis. For example, substrates 12 and 18 could be provided in bulk as sheets of flexible polyester material suitable for use as a circuit carrier rolled onto spools. Preformed conductors 16 could provided in bulk as continuous strips, ribbons, wires or other forms of copper or another conductive material rolled onto spools. Substrates 12 and 18 and conductors 16 could be unrolled from the respective spools, joined together as set forth above, and rolled onto a take-up spool to form a roll of conductor assembly 10 or cut into sections to form conductors assemblies 10 of any desired shape and size. Alternatively, substrates 12 and 18 could be unrolled from the respective spools, conductors 16 could be printed or otherwise deposited onto one or both of substrates 12 and 18, substrates 12 and 18 could be joined together as set forth above, and the assembly could be rolled onto a take-up spool as a roll of conductor assembly 10 or cut into sections to form conductors assemblies 10 of any desired shape and size.

FIGS. 1 and 2 illustrate conductor array 14 as including a plurality of generally elongated conductors 16 arranged in parallel. Conductors 16 could have any suitable length or lengths. Conductor array 14 is shown as including five conductors 16. In other embodiments, conductor array 14 could include more (as many as practical) or fewer (as few as one) than five conductors 16. The overall length and width of array 14 could be selected as desired.

In FIG. 2, each conductor 16 is shown as a plurality of diamond-shaped portions 34 connected by connecting portions 36. The diamond-shaped portions are illustrated as being generally square, but the angles between adjacent sides could be other than right angles. Connecting portions 36 are illustrated as relatively narrow and substantially linear, but could take other forms, as well. In other embodiments, conductors 16 could have other forms. For example, in FIGS. 1 and 3-9, conductors are shown as a plurality of interconnected diamond-shaped portions 34, the free corners of which have been truncated (sometimes referred to herein as “truncated diamonds”). This configuration can allow for closer spacing of adjacent conductors 16. Alternatively, conductors 16 could be embodied as pluralities of rectangles, circles, ellipses, or other regular or irregular shapes connected by connecting portions similar to connecting portions 36. In some embodiments, conductors 16 could take the form of substantially straight wires or ribbons of a suitable width, as would be understood by one skilled in the art.

Conductors 16 could have any suitable width or widths. In an illustrative embodiment wherein conductors 16 are embodied as interconnected diamond-shaped portions, such as that illustrated in FIG. 2, the diamond-shaped portions of conductors 16 could be generally square, with the sides thereof having lengths of about 6 mm. In other embodiments, the sides of the diamond-shaped portions could have shorter or greater lengths. For example, the sides of the diamond-shaped portions could be as short as 1 mm (or shorter) or as long as 15 mm or 20 mm (or longer) or any intermediate length. In illustrative embodiments wherein conductors 16 are embodied as truncated diamonds, such as those illustrated in FIGS. 1 and 3-9, the truncated diamonds could have similar dimension prior to truncation of the free corners, which could be truncated as desired.

The spacing between adjacent pairs of conductors 16 in a particular array 14 could be set as desired. For example, the spacing between conductors 16 could range from 0.2-2.0 mm or, more preferably, from 0.5-1.0 mm. In other embodiments, the spacing between conductors could be less than 0.2 mm or greater than 2.0 mm, as desired. One skilled in the art would recognize that the overall conductor pitch could be limited by the width of the individual conductors 16.

In any event, the spacing between conductors 16 in a particular array typically would be substantially similar. In some embodiments, however, the spacing between certain pairs of conductors 16 in a particular array 14 could differ from the spacing between other pairs of conductors 16 in the particular array 14. For example, a given pair of conductors 16 could be spaced more closely together than another pair of conductors 16.

In embodiments wherein conductors 16 take other forms, conductors 16 can be sized as desired. For example, in embodiments wherein conductors 16 are substantially straight wires or ribbons, conductors 16 could have widths ranging from 0.5 mm or narrower to 25 mm or wider. In such embodiments, the center-to-center conductor spacing (or pitch) typically would be about 0.5 mm or less to about 25 mm or more. Typically, all of conductors 16 within a particular conductor array 14 would have substantially similar or identical shapes and widths. In some embodiments, however, the various conductors within a particular conductor array 14 could have substantially dissimilar shapes and/or widths.

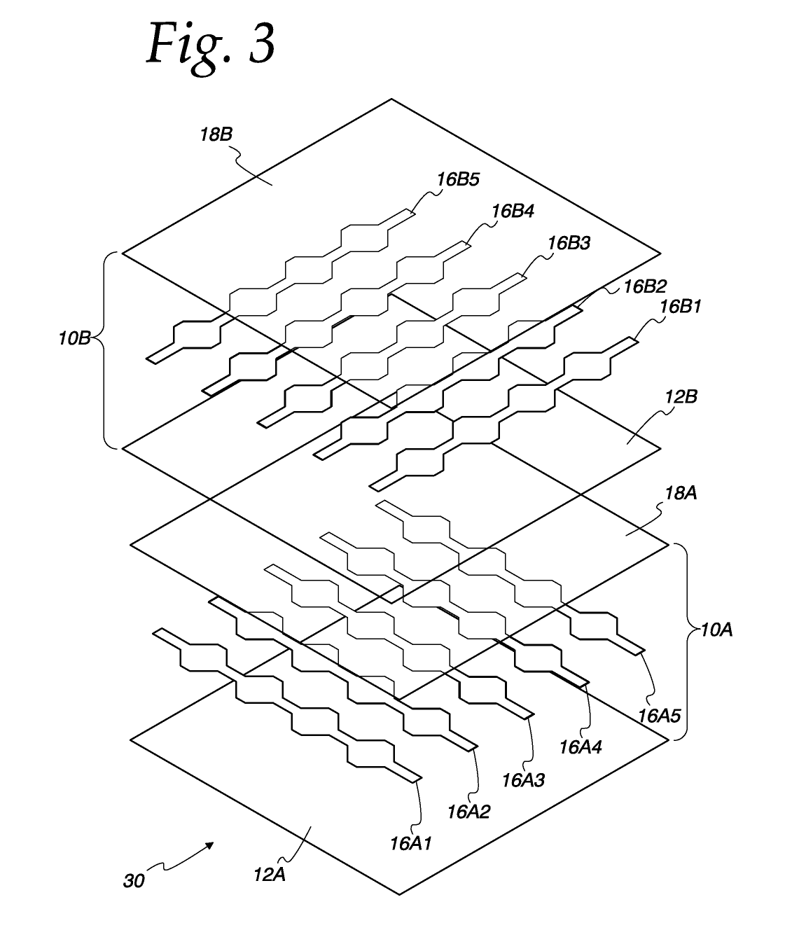

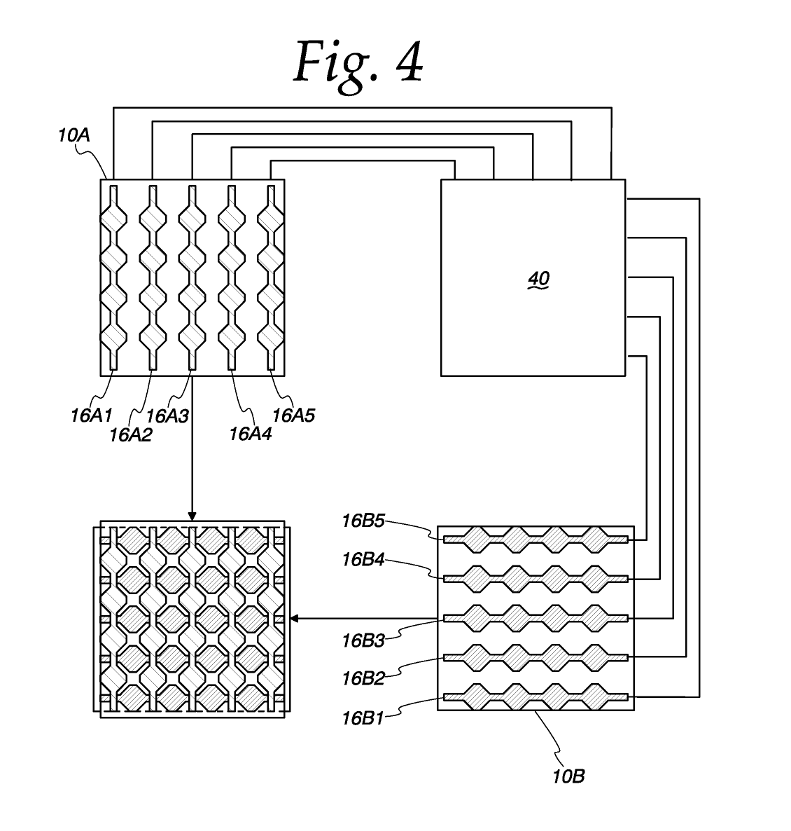

FIGS. 3 and 4 illustrate a sensor array 30 including a pair of conductor assemblies 10A and 10B, each having the structure of conductor assembly 10 as set forth above. More particularly, conductor assembly 10A includes a first substrate 12A, a second substrate 18A and an array 14A of conductors 16A disposed between first substrate 12A and second substrate 18A. Similarly, conductor assembly 10B includes a first substrate 12B, a second substrate 18B and an array 14B of conductors 16B disposed between first substrate 12B and second substrate 18B.

Conductor assemblies 10A and 10B could be joined back-to-back (for example, with second substrate 18A of conductor assembly 10A abutting first substrate 12B of conductor assembly 10B). Alternatively, conductor assemblies 10A and 10B could be separated by some intervening structure or void, for example, another substrate or an air gap. Conductor assemblies 10A and 10B could be joined to each other using any suitable means, for example, an adhesive layer, ultrasonic welding, or others, as would be understood by one skilled in the art.

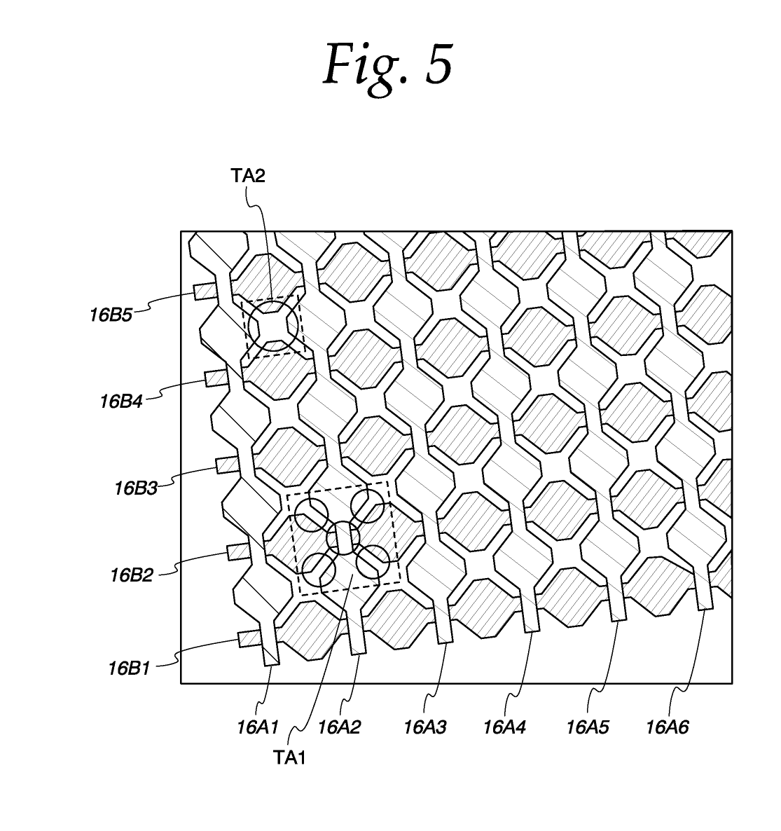

Preferably, conductor assemblies 10A and 10B are arranged such that connecting portions 36 of conductors 16A cross connecting portions 36 conductors 16B and such that diamond-shaped portions of conductors 16B do not overlie diamond-shaped portions of conductors 16A. In some embodiments, a portion of the diamond-shaped portions of conductors 16B could overlie a portion of the diamond-shaped portions of conductors 16A. In FIGS. 3 and 4, conductors 16A are illustrated as crossing conductors 16B at right angles. In other embodiments, conductors 16A could cross conductors 16B at other angles or in other orientations. FIG. 5 is a plan view of sensor array 30 with substrates 12A, 12B, 18A, 18B omitted to more clearly show the relationship between conductor arrays 14A, 14B of assemblies 10A, 10B.

As discussed above, all of conductors 16A typically would be of substantially similar or identical shape and width and would be substantially equally spaced. Also, all of conductors 16B typically would be of substantially similar or identical shape and width and would be substantially equally spaced. Conductors 16B, however, could be of substantially different shape and/or width than conductors 16A and could be spaced differently, as well.

The spacing between layers of conductors 16A and 16B would be a function of at least the thickness of the dielectric layer(s) separating them. In an embodiment, this spacing could be about 0.5 mm. In other embodiment, the spacing could be greater or lass than 0.5 mm, as desired and/or practical.

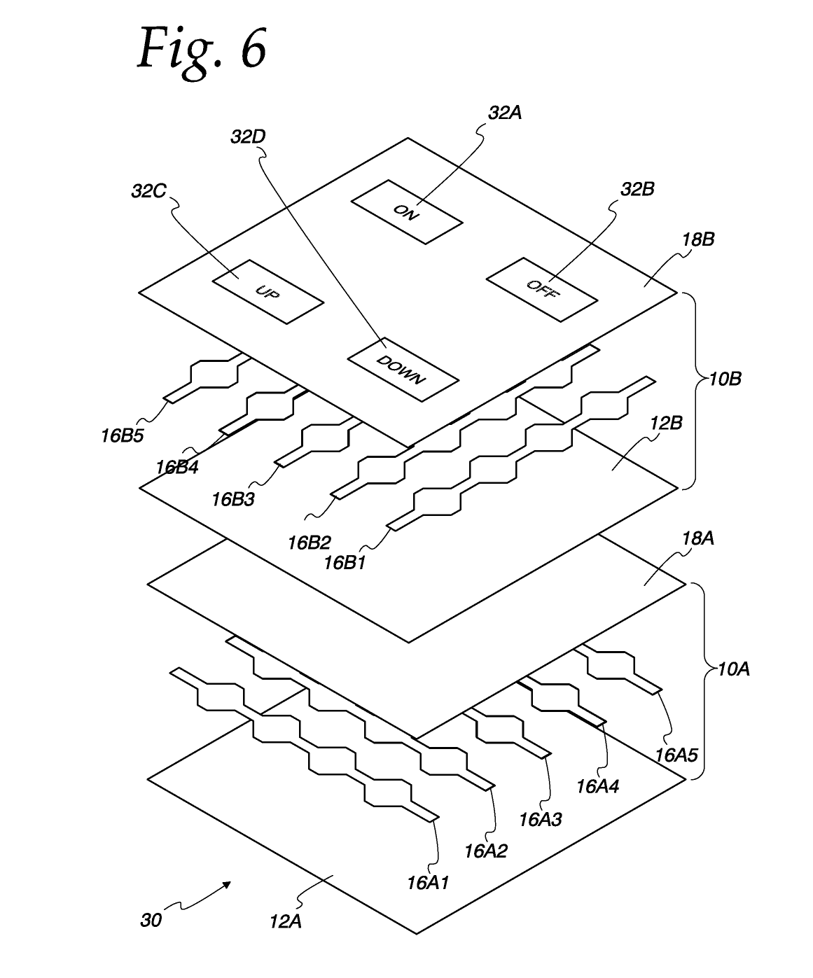

FIG. 6 illustrates a sensor array 30 including conductor assembly 10A and conductor assembly 10B wherein substrate 18B of conductor assembly 10B defines four discrete areas 32A-32D labeled “ON”, “OFF”, “START”, and “STOP”, respectively. Each of discrete areas 32A-32D overlies a specific portion of conductor array 14A and conductor array 14B. Therefore, each of discrete areas 32A-32D overlies a specific portion of one or more of conductors 16A and conductors 16B. The specific portion could, but need not, include an area wherein a conductor 16 of conductor array 14A crosses over a conductor 16B of conductor array 14B. As shown in FIG. 6, discrete area 32A overlies portions of conductors 16A4, 16A5, 16B4 and 16B5; discrete area 32B overlies portions of conductors 16A4, 16A5, 16B1 and 16B2; discrete area 32C overlies portions of conductors 16A1, 16A2, 16B4 and 16B5; and discrete area 32D overlies portions of conductors 16A1, 16A2, 16B1 and 16B2. Also as shown in FIG. 6, no portion of discrete areas 32A-32D overlies conductors 16A3 or 16A3.

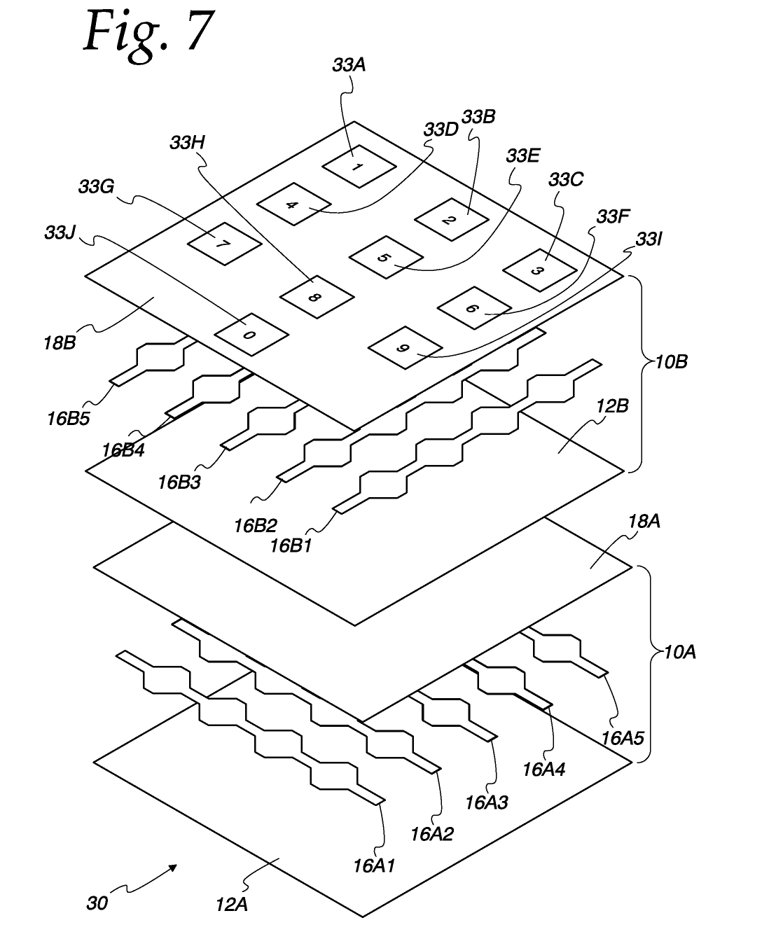

FIG. 7 illustrates another array 30 including an upper assembly 10A and a lower assembly 10B wherein substrate 18A of upper array 10A defines ten touch surfaces 33A-33J labeled with digits “1” through “0”, respectively. Each of touch surfaces 33A-33J overlies a specific portion of conductor array 14A and conductor array 14B. The specific portion could, but need not, include an area wherein a conductor 16 of conductor array 14A crosses over conductor array 14B. As shown in FIG. 7, discrete area 33A overlies portions of conductors 16A4, 16A5, and 16B5; discrete area 33B overlies portions of conductors 16A4, 16A5, and 16B3; discrete area 33C overlies portions of conductors 16A4, 16A5, and 16B1; discrete area 33D overlies portions of conductors 16A3, 16A4, and 16B5; discrete area 33E overlies portions of conductors 16A3, 16A4, and 16B3; discrete area 33F overlies portions of conductors 16A3, 16A3, and 16B1; discrete area 33G overlies portions of conductors 16A2, 16A3, and 16B5; discrete area 33H overlies portions of conductors 16A2, 16A3, and 16B3; discrete area 33I overlies portions of conductors 16A2, 16A3, and 16B1; and discrete area 33J overlies portions of conductors 16A1, 16A2, and 16B3.

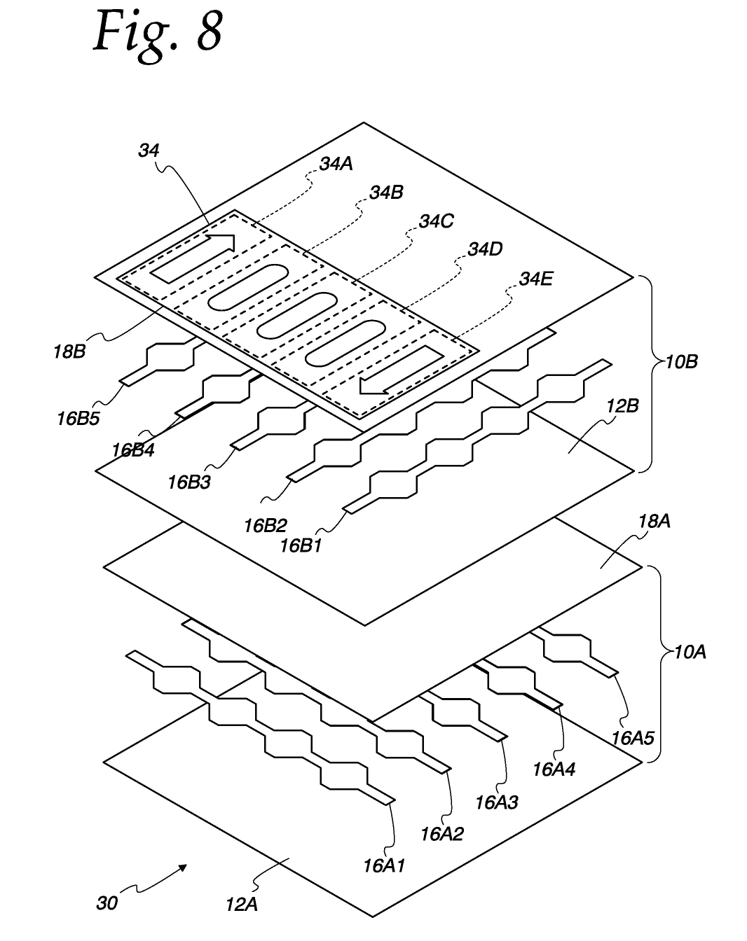

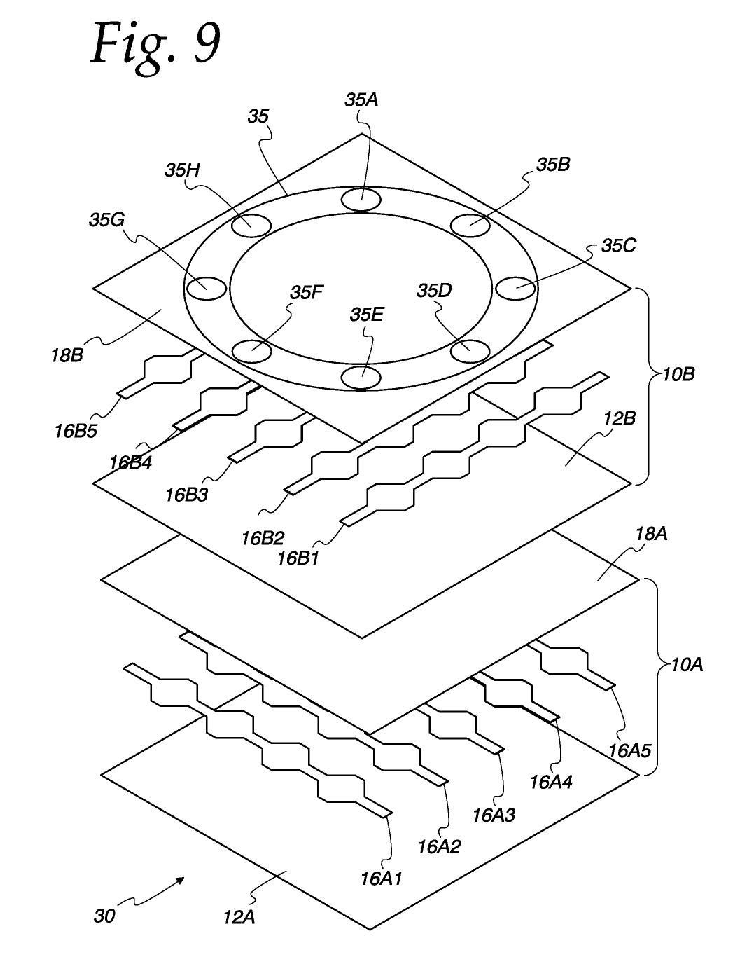

FIG. 8 illustrates yet another array 30 including an upper assembly 10A and a lower assembly 10B wherein substrate 18A of upper array 10A defines a virtual slider 34 having a “continuum” of touch surfaces 34A-34E extending from touch surface 34A (also designated with a down arrow) to touch surface 34E (also designated with an up arrow) and three intervening touch surfaces 34B-34D therebetween. FIG. 9 illustrates still another array 30 including an upper assembly 10A and a lower assembly 10B wherein substrate 18A of upper array 10A defines a virtual wheel or rotary knob 35 having a “continuum” of touch surfaces including at least touch surfaces 35A-35H. One skilled in the art would recognize that the various touch surfaces set forth above in connection with the FIGS. 8 and 9 embodiments overlie corresponding portions of conductors 16Ax and 16By in manners similar to those described above in connection with the FIGS. 6 and 7 embodiments.

As shown in FIG. 4, each conductor 16A, 16B of conductor assemblies 10A, 10B can be coupled to a control circuit 40 by leads 17A, 17B connected to one or both ends of each conductor 16A, 16B. Such leads could be disposed on one or more flexible tails (not shown) extending from one or more of substrates 12A, 12B, 16A, 16B or otherwise. A connector (not shown) could be provided to enable connection of leads 17A, 17B to other circuitry, for example, control circuit 40 as discussed below. For clarity, FIG. 4 shows leads 17A, 17B coupled to only one end of each conductor 16A, 16B. Also for clarity, leads 17A, 17B are not shown in the other drawings.

Control circuit 40 can have signal generation means for providing excitation signals to individual ones of conductors 16A, 16B and detection means for detecting the presence of a finger or other object (that is, a stimulus) near individual ones of conductors 16A, 16B using capacitive sensing or another technology, as would be understood by one skilled in the art and as discussed further below. For example, control circuit 40 can be adapted to detect a finger or other object touching or in proximity to a portion of substrate 12A or substrate 18B that is in proximity to one or more of conductors 16A, 16B. The signal generation means and detection means could be adapted to use principles of self-capacitance and/or mutual capacitance, as would be recognized by one skilled in the art and as may be suggested by the discussions of operation below. Generally, detection means adapted to use principles of mutual capacitance may be preferable in embodiments in which it is desired to simultaneously detect multiple touches (touches at several locations) to substrate 12A and/or substrate 18B.

With reference to FIG. 5, control circuit 40 could be programmed to provide a first control output in response to a detection of a stimulus proximate any of the circles within the box labeled TA1, a second control output in response to detection of a stimulus to the circle within the box labeled TA2, and a null control output in response to a stimulus proximate any other combination of conductors 16A, 16B (or lack of a stimulus proximate any of conductors 16A, 16B).

Control circuit 40 (or another circuit and/or microprocessor connected thereto) can be programmed with software and/or firmware (or implemented with hardware or otherwise) to provide various predetermined control outputs in response to control circuit 40 detecting a stimulus to a particular conductor 16A and a particular conductor 16B at substantially the same time (the design of the control circuit might preclude it from detecting a stimulus to more than one conductor at exactly the same time), as might occur when a user touches or brings a finger near a corresponding portion of substrate 12A or substrate 18B. For example, with reference to FIG. 6, control circuit 40 could include a microprocessor programmed to provide a first control output when it substantially simultaneously detects a stimulus to at least one of conductors 16A and at least one of conductors 16B underlying touch surface 32A. More particularly, control circuit 40 could be programmed to provide the first control output when it substantially simultaneously detects a stimulus to one or more of conductor pairs 16A5 and 16B5, 16A4 and 16B5, 16A5 and 16B4, and 16A4 and 16B4.

Similarly, control circuit 40 can be programmed to provide a second control output in response to control circuit 40 detecting a stimulus to another particular pair of conductors 16A and 16B at substantially the same time as might occur when a user touches or brings a finger near another corresponding portion of substrate 12A or substrate 18B. For example, control circuit 40 could be programmed to provide a second control output when it substantially simultaneously detects a stimulus to at least one of conductors 16A and at least one of conductors 16B underlying touch surface 32D. More particularly, control circuit 40 could be programmed to provide the second control output when it substantially simultaneously detects a stimulus to one or more of conductor pairs 16A1 and 16B1, 16A2 and 16B1, 16A2 and 16B1, and 16A2 and 16B2.

As would be recognized by one skilled in the art, control circuit 40 can be programmed to provide further control outputs in response to stimuli to other predetermined pairs of conductors 16A and 16B. The locations of such conductor pairs typically would correspond to the locations of respective predetermined touch surfaces on substrate 12A and/or 18B.

Control circuit 40 also can be programmed to provide a null control output (which could be yet another predetermined control output or no control output at all) in response to the detection of a stimulus to only a single conductor 16A, 16B or to the lack of detection of a stimulus to any of conductors 16A, 16B. Control circuit 40 further can be programmed to provide a null control output in response to the substantially simultaneous detection of a stimulus to one of conductors 16A and one of conductors 16B not corresponding to touch surfaces 32A-32D or other particular, predetermined portions of substrate 12A or substrate 18B. For example, with reference to FIG. 6, control circuit 40 could be programmed to provide a null control output in response to substantially simultaneous detection of a stimulus proximate conductor 16A3 and conductor 16B3 or any other conductor pair that does not underlie any of touch surfaces 32A-32D.

With reference to FIG. 7, control circuit 40 similarly can be programmed to provide particular, predetermined control outputs in response to substantially simultaneous detection of stimuli to predetermined pairs of conductors 16A and 16B underlying touch surfaces 33A-33J and a null control output in response to detection of a stimulus to only a single conductor 16A, 16B, substantially simultaneous detection of a stimulus or stimuli to pairs of conductors 16A and 16B not underlying touch surfaces 33A-33J or to the lack of detection of a stimulus to any of conductors 16A, 16B.

With reference to FIGS. 8 and 9, control circuit 40 similarly could be programmed to provide particular, predetermined control outputs in response to substantially simultaneous detection of stimuli to predetermined pairs of conductors 16A and 16B underlying touch surfaces 34 and 35A-35H, respectively, and a null control output in response to detection of a stimulus to only a single conductor 16A, 16B, substantially simultaneous detection of a stimulus or stimuli to pairs of conductors 16A and 16B not underlying any of touch surfaces 34 and 35A-35H, or to the lack of detection of a stimulus to any of conductors 16A, 16B.

In some embodiments, sensor array 30 can be attached to a separate user interface substrate (not shown) using adhesives or other means, as would be understood by one skilled in the art. In such embodiments, the labels (or decorations) referred to in the foregoing discussion of FIGS. 6-8 above could be applied to the separate user interface substrate instead of to substrate 18B, and the stimuli detected by control circuit 40 could be stimuli to the corresponding portions of the separate user interface substrate, as would be understood by one skilled in the art.

Because control circuit 40 can be hardwired or programmed with software to respond in particular, predetermined ways to stimuli to particular, predetermined portions of sensor array 30 (and/or a separate user interface panel), a single sensor array 30 can be used in any number of user interface applications having any number of touch surface layouts without modification to the underlying structure or orientation of conductors 16A, 16B. For example, FIGS. 6-8 depict substantially different layouts of touch surfaces 32A-32D, 33A-33J, 34A-34E and 35A-35H, respectively, on a single form of sensor array 30. Control circuit 40 can be programmed in a first way to operate as discussed above in connection with the FIG. 6 embodiment, in a second way to operate as discussed above in connection with the FIG. 7 embodiment, in a third way to operate as discussed above in connection with the FIG. 8 embodiment, and in a fourth way to operate as discussed above in connection with the FIG. 9 embodiment. One skilled in the art would recognize that control circuit 40 could be programmed in other ways, as desired, to control or otherwise operate with interfaces having other touch surface layouts or configurations. As such, sensor array 30 can have substantially universal application.

Array 30 is described above as being made from two pre-fabricated conductor assemblies 10A, 10B. In other embodiments, one of layers 18A, 12B could be omitted so that only a single dielectric layer is present between conductors 16A and 16B. In other embodiments, additional dielectric layers could be present between conductors 16A and 16B. In further embodiments, conductors 16A, 16B could be disposed on opposite sides of a substrate (for example, a printed wiring board or flexible circuit carrier) without discrete outer dielectric layers. Discrete outer dielectric layers optionally could be added to such a structure.

The structures described above could be used in numerous applications, and could be scaled as desired. Generally, it may be desirable to increase the conductor size/width/pitch with increasing size of the application. For example, it may be desirable to use a relatively small conductor size/pitch/width in a user interface panel for a small appliance, such as a blender, and to use a relatively large conductor size/pitch/width in a user interface panel for a large appliance, such as a range. Although relatively small conductor size/pitch/width could be used in a large scale application as well as a small scale application, it could be less complex and costly to use a relatively large conductor size/pitch/width wherever feasible because it could involve the use of less overall conductive material and processing power. More particularly, relatively large scale conductors could be embodied in a partially open, rather than solid, form. Also, an array of relatively large scale conductors would involve relatively few conductors per unit of array area, thus reducing the amount processing requirements for the control circuit, as would be understood by one skilled in the art. An excessively large conductor size/pitch/width, however, could negatively impact the ability to configure the array to emulate discrete, individual sensors, at certain predetermined locations of the array.

The foregoing description and accompanying drawings are intended to illustrate the principles of the invention and not to limit its scope. One skilled in the art would recognize that the disclosed embodiments could be modified in various ways without departure form the scope of the invention as defined by the following claims. Also, to the extent that specific features might be discussed herein only in connection with a specific embodiment, the features discussed in connection with any embodiment generally could be used in connection with any other embodiment except to the extent that context indicates otherwise.

1. An apparatus comprising:
a first conductor array comprising a first dielectric substrate, a first plurality of conductors disposed on said first dielectric substrate, and a second dielectric substrate disposed on said first plurality of conductors;
a second conductor array comprising a third dielectric substrate, a second plurality of conductors disposed on said third dielectric substrate, and a fourth dielectric substrate disposed on said second plurality of conductors; and
a control circuit electrically coupled to each of said first plurality of conductors and said second plurality of conductors;
wherein said second conductor array is disposed on said first conductor array such that individual ones of said first plurality of conductors cross individual ones of said second plurality of conductors;
wherein said control circuit selectively provides excitation signals to individual ones of said first plurality of conductors and said second plurality of conductors;
wherein said control circuit detects stimuli proximate individual ones of said first plurality of conductors and said second plurality of conductors; and
wherein said control circuit provides a first control output in response to said control circuit substantially simultaneously detecting a stimulus proximate a predetermined one of said first plurality of conductors and a predetermined one of said second plurality of conductors and said control circuit provides a null control output in response to said control circuit simultaneously detecting a stimulus proximate at least one other combination of one of said first plurality of conductors and one of said second plurality of conductors.

2. The apparatus of claim 1 wherein said conductors of said first conductor array are generally parallel to each other and wherein said conductors of said second conductor array are generally parallel to each other.

3. The apparatus of claim 2 wherein said conductors of said first conductor array are generally perpendicular to said conductors of said second conductor array.

4. The apparatus of claim 1 wherein said conductors comprise copper stampings.

5. The apparatus of claim 1 wherein said conductors comprise conductive ink.

6. The apparatus of claim 1 wherein said conductors comprise wires.

7. The apparatus of claim 1 wherein said conductors comprise ribbons.

8. The apparatus of claim 1 wherein each of said conductors comprises a plurality of relatively wide portions connected by a corresponding plurality of substantially narrow portions.

9. The apparatus of claim 1 wherein said conductors are substantially opaque.

10. The apparatus of claim 1 wherein any of said dielectric substrates is substantially opaque.

11. The apparatus of claim 1 wherein any of said dielectric substrates comprises a polyester film.

12. The apparatus of any claim 1 wherein said dielectric substrate comprises a wiring board.

13. The apparatus of claim 1 wherein at least a portion of said first dielectric substrate is integrated with said second dielectric layer substrate.

14. The apparatus of claim 1 wherein portions of said first dielectric substrate are ultrasonically welded to portions of said second dielectric substrate.

15. The apparatus of claim 1 wherein individual ones of said first plurality of conductors are separated from each other by about 0.1-2.0 mm.

16. The apparatus of claim 1 wherein said conductors comprise a plurality of diamond shapes connected by at least one connecting portion.

17. The apparatus of claim 16 wherein said diamond shapes have sides about 1.0-20.0 mm in length.

18. The apparatus of claim 1 wherein said conductors comprise a plurality of truncated diamond shapes connected by at least one connecting portion.

19. The apparatus of claim 16 wherein said diamond shapes have sides about 1.0-20.0 mm in length prior to truncation.

20. An apparatus comprising:
a first conductor array comprising a first dielectric substrate, a first plurality of conductors disposed on said first dielectric substrate, and a second dielectric substrate disposed on said first plurality of conductors;
a second conductor array comprising a third dielectric substrate, at least one conductor disposed on said third dielectric substrate, and a fourth dielectric substrate disposed on said at least one conductor; and
a control circuit electrically coupled to each of said first plurality of conductors and said at least one conductor of said second conductor array;
wherein said second conductor array is disposed on said first conductor array such that individual ones of said first plurality of conductors cross said at least one conductor of said second conductor array;
wherein said control circuit selectively provides excitation signals to individual ones of said first plurality of conductors and said at least one conductor of said second conductor array;
wherein said control circuit detects stimuli proximate individual ones of said first plurality of conductors and said at least one conductor of said second conductor array; and
wherein said control circuit provides a first control output in response to said control circuit substantially simultaneously detecting a stimulus proximate a predetermined one of said first plurality of conductors and a predetermined one of said at least one conductor of said second conductor array and said control circuit provides a null control output in response to said control circuit simultaneously detecting a stimulus proximate at least one other combination of one of said first plurality of conductors and one of said at least one conductor of said second conductor array.

21. An apparatus comprising:
a first conductor array comprising a first plurality of conductors;
a second conductor array comprising at least one conductor;
a dielectric substrate disposed between said first conductor array and said second conductor array; and
a control circuit electrically coupled to each of said conductors of said first conductor array and said second conductor array;
wherein said second conductor array is generally parallel to said first conductor array and arranged such that individual ones of said first plurality of conductors cross said at least one conductor of said second conductor array;
wherein said control circuit selectively provides excitation signals to individual ones of said first plurality of conductors and said at least one conductor of said second conductor array;
wherein said control circuit detects stimuli proximate individual ones of said first plurality of conductors and said at least one conductor of said second conductor array; and
wherein said control circuit provides a first control output in response to said control circuit substantially simultaneously detecting a stimulus proximate a predetermined one of said first plurality of conductors and a predetermined one of said at least one conductor of said second conductor array and said control circuit provides a null control output in response to said control circuit simultaneously detecting a stimulus proximate at least one other combination of one of said first plurality of conductors and one of said at least one conductor of said second conductor array.

22. The apparatus of claim 21 wherein said at least one conductor of said second conductor array comprises a second plurality of conductors.
